(19) United States
(12) Patent Application Publication
(10) Pub. No.: US 2019/0214281 A1
(43) Pub. Date: Jul. 11, 2019

(54) HEAT TREATING APPARATUS, COOLING METHOD FOR HEAT PLATE AND RECORDING MEDIUM

(71) Applicant: Tokyo Electron Limited, Tokyo (JP)

(72) Inventor: Kenji Endo, Koshi City (JP)

(21) Appl. No.: 16/242,107

(22) Filed: Jan. 8, 2019

(30) Foreign Application Priority Data
Jan. 9, 2018 (JP) 2018-001257

(51) Int. Cl. H01L 21/67; C23C 16/52; C23C 16/458; C23C 16/46; H01L 21/677; H01L 21/687

(52) U.S. Cl. CPC H01L 21/67109; C23C 16/52; C23C 16/4586; C23C 16/463; H01L 21/68707; H01L 21/67253; H01L 21/67103; H01L 21/6773; H01L 21/67248

(57) ABSTRACT

A cooling method for a heat plate includes a first process of acquiring correlation data between a temperature of a heat plate configured to supply heat to a substrate and a cooling time required for the heated substrate at the corresponding temperature to be cooled to a target temperature by a cooling plate; a second process of acquiring the temperature of the heat plate by a temperature sensor; a third process of placing, after the second process, the substrate on the heat plate; a fourth process of calculating, after the second process, the cooling time corresponding to the temperature acquired in the second process based on the correlation data and the temperature acquired in the second process; and a fifth process of placing, after the fourth process, the substrate on the cooling plate and cooling the substrate for at least the cooling time calculated in the fourth process.

### CROSS-REFERENCE TO RELATED APPLICATION

This application claims the benefit of Japanese Patent Application No. 2018-001257 filed on Jan. 9, 2018, the entire disclosure of which is incorporated herein by reference.

### TECHNICAL FIELD

The various aspects and embodiments described herein pertain generally to a heat treating apparatus, a cooling method for a heat plate and a recording medium.

### BACKGROUND

Patent Document 1 discloses a heat treating apparatus equipped with a heat plate configured to heat a substrate and a cooling plate configured to cool the substrate. This heat treating apparatus has a function of heating a coating film formed on a surface of the substrate along with the substrate.

For example, when reducing a set temperature of the heat plate, performing maintenance of the heat plate, and so forth, it is desirable that the temperature of the heat plate is reduced as quickly as possible to improve productivity. For the purpose, in the aforementioned heat treating apparatus, the heat plate is cooled by cooling a cooling body to a preset temperature with the cooling plate and placing the cooled cooling body at the heat plate for a preset time period.

Patent Document 1: Japanese Patent Laid-open Publication No. H11-219887

### SUMMARY

In view of the foregoing, exemplary embodiments provide a heat treating apparatus and a cooling method for a heat plate capable of cooling the heat plate in a shorter period of time, and a recording medium.

### Example 1

A heat treating apparatus includes a heat plate configured to supply heat to a substrate; a cooling plate configured to cool the substrate; a first transfer device configured to transfer the substrate between the heat plate and the cooling plate; a temperature sensor configured to acquire a temperature of the heat plate; a storage unit configured to store therein correlation data showing a relationship between the temperature of the heat plate and a cooling time required for the substrate heated by the heat plate at the corresponding temperature to be cooled to a target temperature by the cooling plate; and a control unit. The control unit performs: a first processing of acquiring the temperature of the heat plate by the temperature sensor; a second processing of placing, after the first processing, the substrate on the heat plate by controlling the first transfer device; a third processing of calculating, after the first processing, the cooling time corresponding to the temperature acquired in the first processing based on the correlation data and the temperature acquired in the first processing; and a fourth processing of placing, after the third processing, the substrate on the cooling plate by controlling the first transfer device and cooling the substrate by the cooling plate for at least the cooling time calculated in the third processing.

In the apparatus of the example 1, the substrate heated by the heat plate is cooled by the cooling plate for the cooling time acquired based on the correlation data and the temperature of the heat plate detected before the substrate is heated. Therefore, the time period during which the substrate is cooled by the cooling plate is not of a uniform length but varies depending on the temperature of the heat plate. That is, if the heat plate is of a relatively high temperature, the substrate heated by this heat plate also has a relatively high temperature, so that the cooling time of the substrate by the cooling plate tends to be lengthened. Meanwhile, if the heat plate is of a relatively low temperature, the substrate heated by this heat plate also has a relatively low temperature, so that the cooling time of the substrate by the cooling plate tends to be shortened. Thus, since the cooling time necessary and sufficient for the temperature of the heat plate is set, the time required for the substrate to reach the target temperature is shortened. Therefore, the heat plate can be cooled in a shorter period of time.

### Example 2

In the apparatus of the example 1, the control unit may further perform: a fifth processing of acquiring, after the second processing, a temperature of the heat plate by the temperature sensor; a sixth processing of placing, after the fifth processing, the substrate on the heat plate by using the first transfer device; a seventh processing of calculating, after the fifth processing, the cooling time corresponding to the temperature acquired in the fifth processing based on the correlation data and the temperature acquired in the fifth processing; and an eighth processing of placing, after the seventh processing, the substrate on the cooling plate by controlling the first transfer device, and cooling the substrate by the cooling plate for at least the cooling time calculated in the seventh processing. In this case, in the course of the first processing to the fourth processing, the heat plate is cooled from a first temperature to a second temperature by the substrate, and the substrate is cooled for a first cooling time by the cooling plate. Subsequently, in the course of the fifth processing to the eighth processing, the heat plate is cooled from the second temperature to a third temperature by the substrate, and the substrate is cooled for a second cooling time by the cooling plate. Since the second temperature acquired before the substrate is placed on the heat plate in the later process is lower than the first temperature acquired before the substrate is placed on the heat plate in the earlier process, the second cooling time is shorter than the first cooling time. Thus, the cooling time of the substrate does not have a uniform length. Accordingly, in case of reducing the temperature of the heat plate greatly by carrying the substrate onto the heat plate and the cooling plate multiple times, it is possible to cool the heat plate in a short period of time.

### Example 3

The apparatus of the example 1 or the example 2 may further includes a second transfer device configured to transfer the substrate to/from the cooling plate.

### Example 4

In the apparatus of the example 3, the target temperature may be set to be equal to or less than the heat resistant temperature of the second transfer device. Accordingly, since the substrate is sufficiently cooled, the deformation, the degradation or the damage of the second transfer device due to the heat from the substrate is suppressed when the second transfer device transfers the substrate. Therefore, it is possible to maintain the function of supporting the substrate by the second transfer device.

### Example 5

In another exemplary embodiment, a cooling method for a heat plate includes a first process of acquiring correlation data showing a relationship between a temperature of a heat plate configured to supply heat to a substrate and a cooling time required for the substrate heated by the heat plate at the corresponding temperature to be cooled to a target temperature by a cooling plate configured to cool the substrate; a second process of acquiring the temperature of the heat plate by a temperature sensor; a third process of placing, after the second process, the substrate on the heat plate; a fourth process of calculating, after the second process, the cooling time corresponding to the temperature acquired in the second process based on the correlation data and the temperature acquired in the second process; and a fifth process of placing, after the fourth process, the substrate on the cooling plate and cooling the substrate by the cooling plate for at least the cooling time calculated in the fourth process. In this case, the same effect as that of the apparatus of the example 1 can be achieved.

### Example 6

The method of the example 5 may further include a sixth process of acquiring, after the third process, the temperature of the heat plate by the temperature sensor; a seventh process of placing, after the sixth process, the substrate on the heat plate; an eighth process of calculating, after the sixth process, the cooling time corresponding to the temperature acquired in the sixth process based on the correlation data and the temperature acquired in the sixth process; and a ninth process of placing, after the eighth process, the substrate on the cooling plate and cooling the substrate by the cooling plate for at least the cooling time calculated in the eighth process. In this case, the same effect as that of the apparatus of the example 2 can be achieved.

### Example 7

The method of the example 5 or the example 6 may further include a tenth process of carrying out, after the fifth process, the substrate from the cooling plate by a transfer device. In this case, the same effect as that of the apparatus of the example 3 is achieved.

### Example 8

In the method of the example 7, the target temperature may be set to be equal to or less than a heat resistant temperature of the transfer device. In this case, the same effect as that of the apparatus of the example 4 is achieved.

In still another exemplary embodiment, an example of a computer-readable recording medium stores thereon computer-executable instructions that, in response to execution, cause a heat treating apparatus to perform a cooling method for the heat plate of any one of the example 5 to the example 8. In this case, the same effect as that of the method of any one of the example 5 to the example 8 can be achieved. In the present disclosure, the computer readable recording medium includes a non-transitory computer recording medium (for example, various kinds of main or secondary memory unit) or a radio signal (transitory computer recording medium) (for example, a data signal which can be provided via a network).

In the heat treating apparatus, the cooling method for the heat plate and the computer-readable recording medium according to the present disclosure, it is possible to cool the heat plate in a shorter period of time.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a perspective view illustrating a substrate processing system;

FIG. 2 is a cross sectional view taken along a line II-II of FIG. 1;

FIG. 3 is a top view illustrating a unit processing block;

FIG. 4 is a cross sectional view of a heat treating unit seen from a side thereof;

FIG. 5 is a cross sectional view of the heat treating unit seen from above;

FIG. 6 is a block diagram illustrating major parts of the substrate processing system;

FIG. 7 is a schematic diagram illustrating a hardware configuration of a controller;

FIG. 8 is a flowchart for describing a method of acquiring correlation data by using a wafer;

FIG. 9 is a schematic diagram for describing a processing sequence for the wafer;

FIG. 10 is a schematic diagram for describing a processing sequence for the wafer;

FIG. 11 is a schematic diagram for describing a processing sequence for the wafer;

FIG. 12 is a schematic diagram for describing a processing sequence for the wafer;

FIG. 13 is a schematic diagram for describing a processing sequence for the wafer; and

FIG. 14 is a flowchart for describing a method of cooling a heat plate by using the wafer.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments will be described in detail with reference to accompanying drawings. However, the various exemplary embodiments are not meant to be anyway limiting, and the present disclosure is not limited thereto. In the following description, same part or parts having same functions will be assigned same reference numerals, and redundant description thereof will be omitted.

[Substrate Processing System]

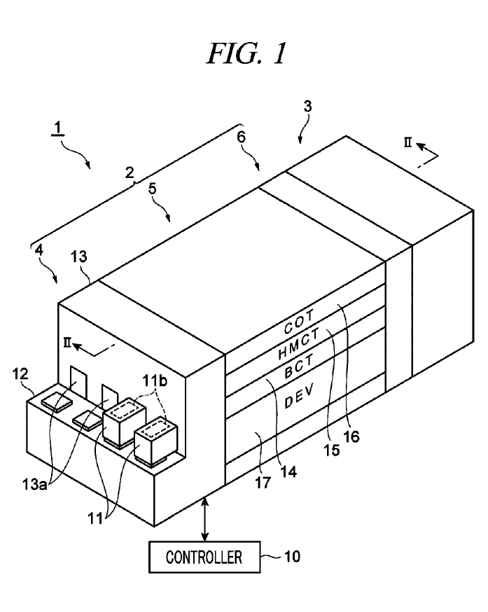

As illustrated in FIG. 1, a substrate processing system 1 (substrate processing apparatus) includes a coating and developing apparatus 2 (substrate processing apparatus), an exposure apparatus 3 and a controller 10 (control unit). The exposure apparatus 3 is configured to perform an exposure processing (pattern exposure) upon a resist film formed on a surface of a wafer W (substrate). To elaborate, an energy line is selectively irradiated to an exposure target portion of the resist film (photosensitive film) by liquid immersion exposure or the like. As the energy line, an ArF excimer laser, a KrF excimer laser, a G-line, an I-line or an extreme ultraviolet (EUV) may be used.

The coating and developing apparatus 2 performs a processing of forming the resist film on the surface of the wafer W before the exposure processing by the exposure apparatus 3 and performs a developing processing on the resist film after the exposure processing. The wafer W may have a circular plate shape, and a part of the circular shape may be notched. Alternatively, the wafer W may have another shape, other than the circular shape, such as a polygonal shape. The wafer W may be, by way of non-limiting example, a semiconductor substrate, a glass substrate, a mask substrate, a FPD (Flat Panel Display) substrate or any of various kinds of substrates. The wafer W may have a diameter ranging from, e.g., 200 mm to 450 mm.

As depicted in FIG. 1 to FIG. 3, the coating and developing apparatus 2 is equipped with a carrier block 4, a processing block 5 and an interface block 6. The carrier block 4, the processing block 5 and the interface block 6 are arranged horizontally.

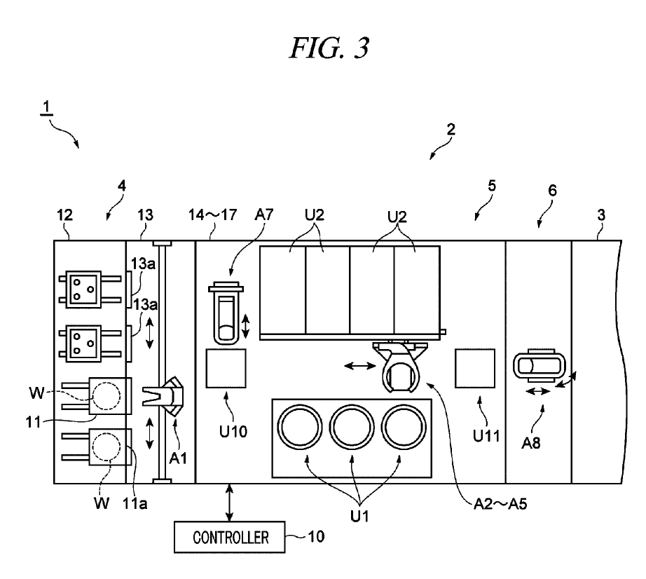

The carrier block 4 includes, as shown in FIG. 1 and FIG. 3, a carrier station 12 and a carry-in/out unit 13. The carrier station 12 is configured to support a multiple number of carriers 11. Each carrier 11 accommodates therein at least one wafer W in a sealed state. An opening/closing door (not shown) for a carry-in/carry-out of the wafer W is provided at a side surface 11a of the carrier 11. The carrier 11 is placed on the carrier station 12 in a detachable manner with the side surface 11a thereof facing the carry-in/out unit 13.

The carry-in/out unit 13 is located between the carrier station 12 and the processing block 5. The carry-in/out unit 13 is equipped with a multiple number of opening/closing door 13a. When the carrier 11 is placed on the carrier station 12, the opening/closing door of the carrier 11 faces the corresponding one of the opening/closing doors 13a. By opening the opening/closing door 13a and the opening/closing door at the side surface 11a, the inside of the carrier 11 and the inside of the carry-in/out unit 13 are allowed to communicate with each other. The carry-in/out unit 13 incorporates therein a transfer arm A1 (second transfer device; transfer device). The transfer arm A1 takes out the wafer W from the carrier 11, delivers the taken wafer W to the processing block 5, receives the wafer W from the processing block 5 and then returns the received wafer W back into the carrier 11.

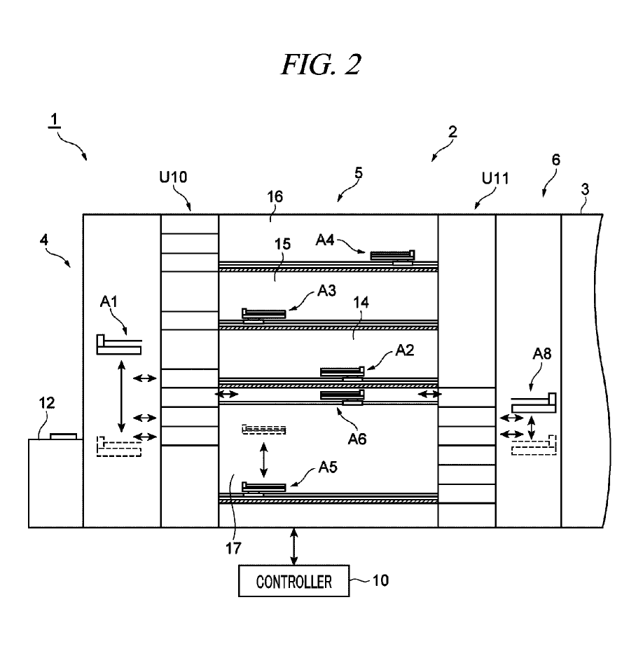

The processing block 5 includes, as shown in FIG. 1 and FIG. 2, modules 14 to 17. These modules are arranged in the order of a module 17, a module 14, a module 15 and a module 16 from a bottom surface side.

The module 14 is configured to form a base film on the surface of the wafer W and is also called a BCT module. The module 14 incorporates therein, as depicted in FIG. 2 and FIG. 3, a plurality of units U1 for coating, a plurality of units U2 (heat treating apparatuses) for heat treatment, and a transfer arm A2 (second transfer device; transfer device) configured to transfer the wafer W into these units U1 and U2. The unit U1 of the module 14 is configured to form a coating film by coating the surface of the wafer W with a coating liquid for forming the base film. The unit U2 of the module 14 is configured to perform the heat treatment by heating the wafer W with, for example, a heat plate 113 (to be described later) and cooling the heated wafer W with, for example, a cooling plate 121 (to be described later). As a specific example, the heat treatment performed in the module 14 may be one for hardening the coating film into the base film. As an example, the base film may be an antireflection (SiARC) film.

The module 15 is configured to form an intermediate film (hard mask) on the base film and is also called a HMCT module. The module 15 incorporates therein, as depicted in FIG. 2 and FIG. 3, a plurality of units U1 for coating, a plurality of units U2 (heat treating apparatuses) for heat treatment, and a transfer arm A3 (second transfer device; transfer device) configured to transfer the wafer W into these units U1 and U2. The unit U1 of the module 15 is configured to form a coating film by coating, on the surface of the wafer W, a coating liquid for forming the intermediate film. The unit U2 of the module 15 is configured to perform the heat treatment by heating the wafer W with, for example, the heat plate 113 (to be described later) and cooling the heated wafer W with, for example, the cooling plate 121 (to be described later). As a specific example, the heat treatment performed in the module 15 may be one for hardening the coating film into the intermediate film. As a non-limiting example, the intermediate film may be a SOC (Spin On Carbon) film or an amorphous carbon film.

The module 16 is configured to form a thermoset and photosensitive resist film on the intermediate film and is also called a COT module. The module 16 incorporates therein, as depicted in FIG. 2 and FIG. 3, a plurality of units U1 for coating, a plurality of units U2 (heat treating apparatuses) for heat treatment, and a transfer arm A4 (second transfer device; transfer device) configured to transfer the wafer W into these units U1 and U2. The unit U1 of the module 16 is configured to form a coating film by coating the intermediate film with a processing liquid (resist) for forming the resist film. The unit U2 of the module 16 is configured to perform the heat treatment by heating the wafer W with, for example, the heat plate 113 (to be described later) and cooling the heated wafer W with, for example, the cooling plate 121 (to be described later). As a specific example, the heat treatment performed in the module 16 may be PAB (Pre Applied Bake) for hardening the coating film into the resist film.

The module 17 is configured to perform a developing processing upon the resist film after being exposed and is also called DEV module. The module 17 incorporates therein, as illustrated in FIG. 2 and FIG. 3, a plurality of units U1 for development, a plurality of units U2 for heat treatment, a transfer arm A5 (second transfer device; transfer device) configured to transfer the wafer W into these units U1 and U2, and a transfer arm A6 configured to transfer the wafer W between shelf units U11 and U10 (to be described later) directly not via the units U1 and U2. The unit U1 of the module 17 is configured to form a resist pattern by removing the resist film partially. The unit U2 of the module 17 is configured to perform the heat treatment by heating the wafer W with, for example, the heat plate 113 (to be described later) and cooling the heated wafer W with, for example, the cooling plate 121 (to be described later). As a specific example, the heat treatment performed in the module 17 may be a heat treatment before a developing processing (PEB: Post Exposure Bake) or a heat treatment after the developing processing (PB: Post Bake).

At the side of the carrier block 4 within the processing block 5, there is provided the shelf unit U10, as shown in FIG. 2 and FIG. 3. The shelf unit U10 is extended from the bottom to the module 15 and partitioned into a multiple number of cells which are arranged in the vertical direction. A transfer arm A7 is provided in the vicinity of the shelf unit U10. The transfer arm A7 is configured to move the wafer W up and down between the cells of the shelf unit U10.

At the side of the interface block 6 within the processing block 5, there is provided the shelf unit U11. The shelf unit U11 is extended from the bottom to an upper portion of the module 17 and partitioned into a multiple number of cells which are arranged in the vertical direction.

The interface block 6 incorporates a transfer arm A8 therein and is connected to the exposure apparatus 3. The transfer arm A8 is configured to take out the wafer W from the shelf unit U11, deliver the taken wafer to the exposure apparatus 3, receive the wafer W from the exposure apparatus 3 and then return the received wafer W back into the shelf unit U11.

The controller 10 controls a partial or overall operation of the substrate processing system 1. Details of the controller 10 will be discussed later.

[Configuration of Unit for Heat Treatment]

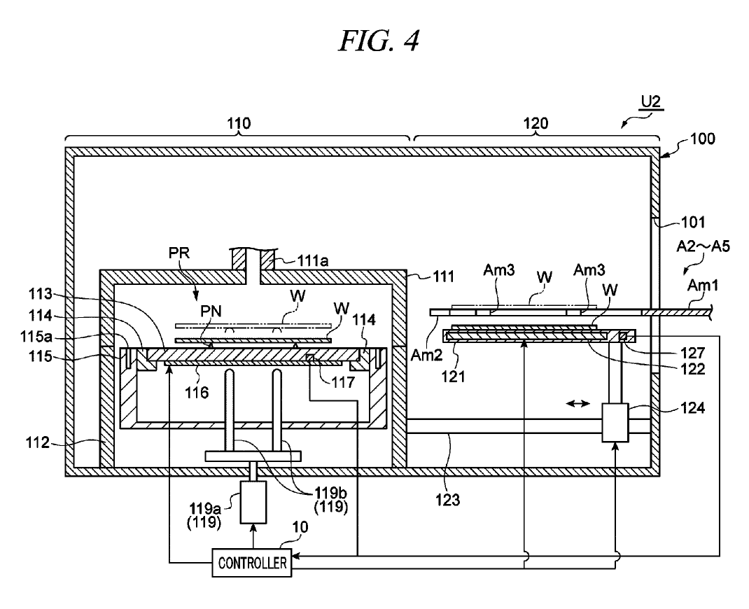

Now, a configuration of the unit U2 for heat treatment will be explained in further detail with reference to FIG. 4 to FIG. 7.

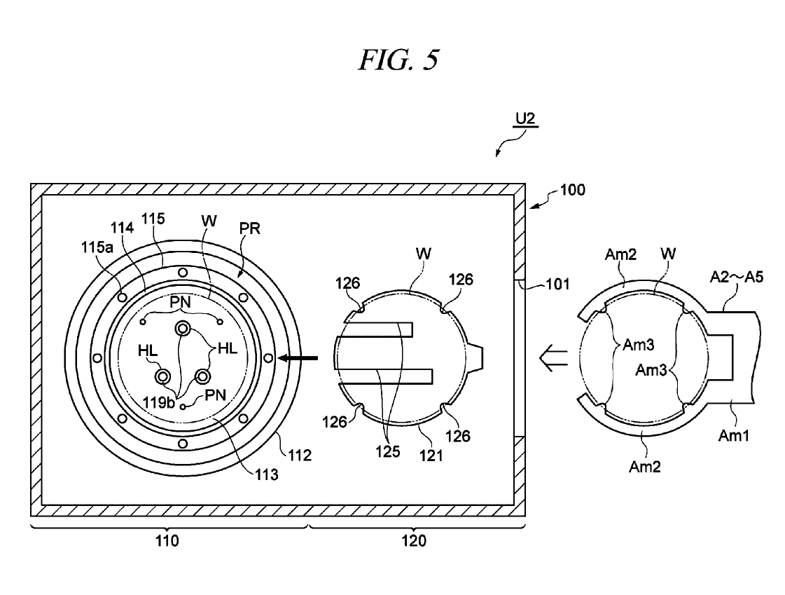

The unit U2 has, within a housing 100, a heating unit 110 configured to heat the wafer W and a cooling unit 120 configured to cool the wafer W, as depicted in FIG. 4 and FIG. 5. A carry-in/out opening 101 through which the transfer arm A2 (A3, A4, A5) can pass is formed at an end surface of the housing 100 corresponding to the cooling unit 120. The transfer arms A2 to A5 are configured to carry the wafer W into the housing 100 and to carry out the wafer W from the housing 100.

The transfer arm A2 (A3 to A5) includes a base end portion Am1 and a pair of arm members Am2, as shown in FIG. 5. Each of the pair of arm members Am2 is extended from the base end portion Am1 toward a leading end side in an arc shape. A plurality of supporting protrusions Am3 is provided on an inner circumferential surface of the arm member Am2. These supporting protrusions Am3 are protruded inwards from the inner circumferential surface of the arm member Am2. When the wafer W is placed on the transfer arm A2 (A3 to A5), the wafer W and leading end portions of the supporting protrusions Am3 are overlapped. Accordingly, the wafer W is supported by the supporting protrusions Am3. Though not shown, the transfer arms A1 and A6 to A8 may have the same structure as that of the transfer arms A2 to A5.

The transfer arms A2 to A5 may be made of a material which is light-weighted and easy to process. The transfer arms A2 to A5 may be made of, but not limited to, a resin. As an example, the resin may be a PEEK (polyetheretherketone) resin, a fluorine resin, or the like. A heat resistant temperature of the transfer arms A2 to A5 may be, by way of example, about 100° C. to about 200° C. The transfer arms A1 and A6 to A8 may have the same material and the same heat resistant temperature as those of the transfer arms A2 to A5.

The heating unit 110 includes, as depicted in FIG. 4 and FIG. 5, a cover member 111 and a heat plate accommodation member 112. The cover member 111 is provided above the heat plate accommodation member 112. As the controller 10 controls a driving source (not shown), the cover member 111 is vertically movable between an upper position spaced apart from the heat plate accommodation member 112 and a lower position where the cover member 111 is placed on the heat plate accommodation member 112. When located at the lower position, the cover member 111 along with the heat plate accommodation member 112 constitutes a processing chamber PR. A gas exhaust port 111a through which a gas is exhausted from the processing chamber PR is provided at a center of the cover member 111.

The heat plate accommodation member 112 has a cylindrical shape and accommodates therein the heat plate 113. A peripheral portion of the heat plate 113 is supported by a supporting member 114. A periphery of the supporting member 114 is supported by a support ring 115 having a cylindrical shape. A gas supply opening 115a opened upwards is formed at a top surface of the support ring 115. Through the gas supply opening 115a, an inert gas is introduced into the processing chamber PR.

The heat plate 113 is a flat plate having a circular shape as shown in FIG. 5. A size of the heat plate 113 is larger than a size of the wafer W. The heat plate 113 is provided with three through holes HL extended through the heat plate 113 in a thickness direction. At least three supporting pins PN configured to support the wafer W are provided on a top surface of the heat plate 113, as depicted in FIG. 4 and FIG. 5. Each supporting pin PN may have a height of, e.g., about 100 μm. A heater 116 configured to heat the heat plate 113 is placed on a bottom surface of the heat plate 113, as shown in FIG. 4. A temperature sensor 117 configured to measure a temperature of the heat plate 113 is provided within the heat plate 113.

An elevating device 119 (first transfer device) is provided below the heat plate 113. The elevating device 119 includes a motor 119a provided at an outside of the housing 100; and three elevating pins 119b configured to be moved up and down by the motor 119a. Each of the elevating pins 119b is inserted into the corresponding one of the through holes HL. When leading ends of the elevating pins 119b are protruded above the heat plate 113 and the supporting pins PN, the wafer W can be placed on the leading ends of the elevating pins 119b. The wafer W placed on the leading ends of the elevating pins 119b is moved up and down as the elevating pins 119b are moved up and down.

The cooling unit 120 is placed adjacent to the heating unit 110, as shown in FIG. 4 and FIG. 5. The cooling unit 120 is equipped with a cooling plate 121 (first transfer device) configured to cool the wafer W placed on the cooling unit 120. The cooling plate 121 is a flat plate having a substantially circular shape as shown in FIG. 5 and is configured to be capable of carrying the wafer W. A size of the cooling plate 121 is larger than the size of the wafer W.

The cooling plate 121 is mounted to a rail 123 elongated toward the heating unit 110, as shown in FIG. 4. The cooling plate 121 is driven by a moving device 124 and is configured to be horizontally movable on the rail 123. The cooling plate 121 moved to the heating unit 110 is located above the heat plate 113. That is, the cooling plate 121 is movable between a position above the heat plate 113 and a position spaced apart from the heat plate 113.

The cooling plate 121 is provided with two slits 125 and a plurality of notches 126, as illustrated in FIG. 5. The slits 125 are extended from end portions of the cooling plate 121 at the side of the heating unit 110 to near a central portion of the cooling plate 121 in an extension direction of the rail 123. With the slits 125, interference between the cooling plate 121 moved to the heating unit 110 and the elevating pins 119b protruded above the heat plate 113 is avoided. Therefore, the cooling plate 121 is capable of transferring the wafer W onto the heat plate 113 and receiving the wafer W from the heat plate 113.

The cooling plate 121 may be made of a metal having high heat conductivity. By way of non-limiting example, the cooling plate 121 may be made of aluminum.

The notches 126 are recessed toward the inside of the cooling plate 121. When the wafer W is placed on the cooling plate 121, the wafer W and leading end portions of the notches 126 are overlapped. These notches 126 are provided at positions respectively corresponding to the supporting protrusions Am3 when the transfer arm A2 (A3 to A5) and the cooling plate 121 are vertically overlapped. Accordingly, when the transfer arm A2 (A3 to A5) is moved up and down with respect to the cooling plate 121, the supporting protrusions Am3 can pass through the corresponding notches 126. Therefore, the wafer W supported by the supporting protrusions Am3 is placed on the cooling plate 121 as the transfer arm A2 (A3 to A5) is moved downwards with respect to the cooling plate 121. Meanwhile, the wafer W placed on the cooling plate 121 is supported by the supporting protrusions Am3 as the transfer arm A2 (A3 to A5) is moved upwards with respect to the cooling plate 121.

As shown in FIG. 4, an elevating device is provided under the cooling plate 121. The elevating device includes a motor provided at an outside of the housing 100 and three elevating pins configured to be moved up and down by the motor. Each of the elevating pins is configured to pass through the slit 125. When leading ends of the elevating pins are protruded above the cooling plate 121, the wafer W can be placed on the leading ends of the elevating pins. The wafer W placed on the leading ends of the elevating pins is moved up and down as the elevating pins is moved up and down.

As illustrated in FIG. 4, a cooling member 122 and a temperature sensor 127 are provided within the cooling plate 121. The cooling member 122 is configured to adjust a temperature of the cooling plate 121 and may be made of, by way of non-limiting example, a Peltier element. The temperature sensor 127 is configured to measure the temperature of the cooling plate 121.

[Configuration of Controller]

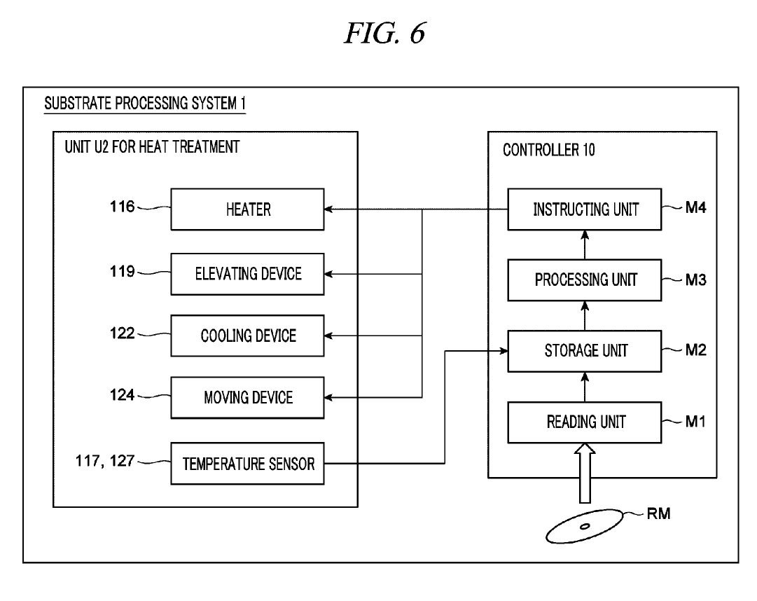

As shown in FIG. 6, the controller 10 includes, as functional modules, a reading unit M1, a storage unit M2, a processing unit M3 and an instructing unit M4. These functional modules are nothing more than divisions of functions of the controller 10 for convenience’ sake, and it does not necessarily imply that hardware of the controller 10 is divided into these modules. Each functional module is not limited to being implemented by execution of a program but may be implemented by a dedicated electrical circuit (for example, a logic circuit) or an ASIC (Application Specific Integrated Circuit) thereof.

The reading unit M1 is configured to read a program from a computer readable recording medium RM. The recording medium RM stores thereon programs for operating the individual components of the substrate processing system 1. The recording medium RM may be, by way of example, but not limitation, a semiconductor memory, an optical recording disk, a magnetic recording disk, a magneto-optical recording disk, or the like.

The storage unit M2 stores therein various types of data. The data stored in the storage unit M2 may be, by way of example, the program read from the recording medium RM by the reading unit M1, the temperature of the heat plate 113 inputted from the temperature sensor 117, and the temperature of the cooling plate 121 inputted from the temperature sensor 127. The storage unit M2 also stores therein correlation data to be described later.

The processing unit M3 processes various types of data. The processing unit M3 generates signals for operating the individual components (for example, the heater 116, the elevating device 119, the cooling member 122 and the moving device 124) of the substrate processing system 1 based on, for example, the various types of data stored in the storage unit M2.

The instructing unit M4 outputs the signals generated by the processing unit M3 to the individual components (for example, the heater 116, the elevating device 119, the cooling member 122 and the moving device 124) of the substrate processing system 1. To elaborate, the instructing unit M4 switches ON/OFF the heater 116 by sending an instruction signal to the heater 116. The instructing unit M4 allows the elevating pin 119b to be moved up or down by sending a moving-up signal or a moving-down signal to the motor 119a. The instructing unit M4 allows a temperature of the cooling member 122 to be adjusted to a preset temperature by sending an instruction signal to the cooling member 122. The instructing unit M4 allows the cooling plate 121 to be moved horizontally along the rail 123 between a first position where the cooling plate 121 is located above heat plate 113 and a second position where the cooling plate 121 is distanced away from the heat plate 113 by sending a driving signal to the moving device 124.

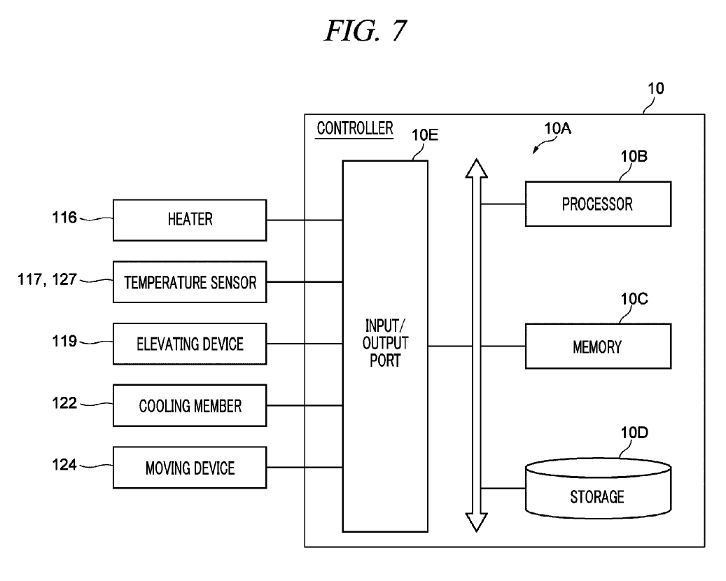

The hardware of the controller 10 is composed of, for example, a single or a plurality of control computers. As a hardware component, the controller 10 has a circuit 10A as shown in FIG. 7, for example. The circuit 10A may be composed of circuitry elements. Specifically, the circuit 10A includes a processor 10B, a memory 10C (storage unit), a storage 10D (storage unit) and an input/output port 10E. The processor 10B constitutes the aforementioned individual components by executing a program in cooperation with at least one of the memory 10C or the storage 10D and performing an input/output of signals via the input/output port 10E. The input/output port 10E performs the input/output of the signals between the processor 10B, the memory 10C and the storage 10D and the various apparatuses of the substrate processing system 1.

In the present exemplary embodiment, the substrate processing system 1 is equipped with the single controller 10. However, the substrate processing system 1 may have a controller group (control unit) composed of a multiple number of controllers 10. In case that the substrate processing system 1 includes the controller group, each of the aforementioned functional modules may be implemented by a single controller 10 or by a combination of two or more controllers 10. In case that the controller 10 is composed of the plurality of computers (circuits 10A), each of the aforementioned functional modules may be implemented by a single computer (circuit 10A) or by a combination of two or more computers (circuits 10A). The controller 10 may have a plurality of processors 10B. In this case, each of the aforementioned functional modules may be implemented by a single processor 10B or by a combination of two or more processors 10B.

[Method of Acquiring Correlation Data by Wafer]

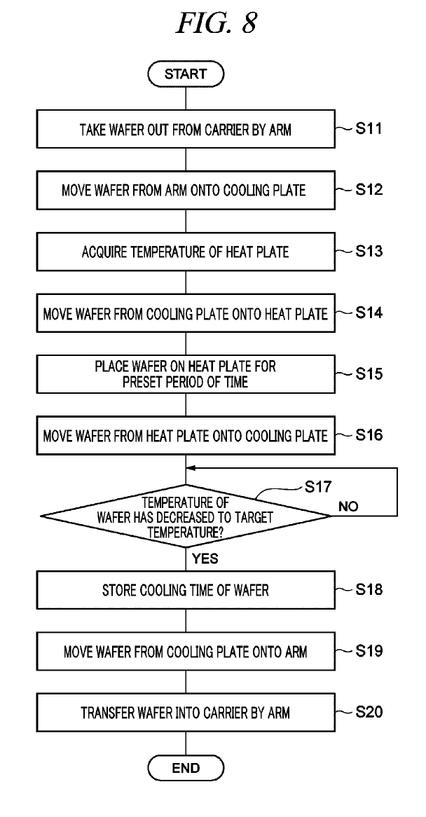

Now, a method of acquiring correlation data by using the above-described unit U2 for heat treatment will be described with reference to FIG. 8 to FIG. 13. Here, the correlation data refers to data indicating a relationship between the temperature of the heat plate 113 and a cooling time required for the wafer W heated by the heat plate 113 to be cooled to a target temperature by the cooling plate 121.

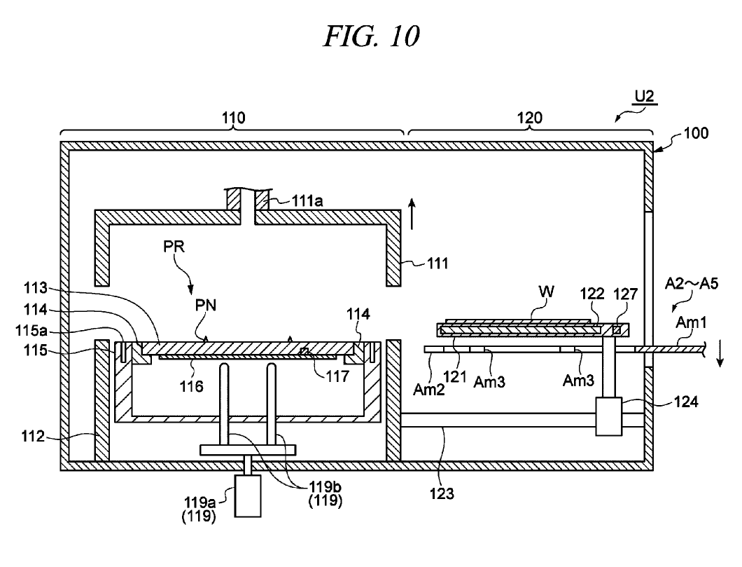

First, the controller 10 controls the transfer arm A1 (A2 to A5) to take out a single sheet of wafer W from the carrier 11 and transfer the wafer W into the housing 100 of the unit U2 (process S11 of FIG. 8). Subsequently, the controller 10 controls the transfer arm A2 (A3 to A5) to be lowered below the cooling plate 121, as shown in FIG. 10. Accordingly, the wafer W supported by the supporting protrusions Am3 of the transfer arm A2 (A3 to A5) is placed on the cooling plate 121 (process S12 of FIG. 8).

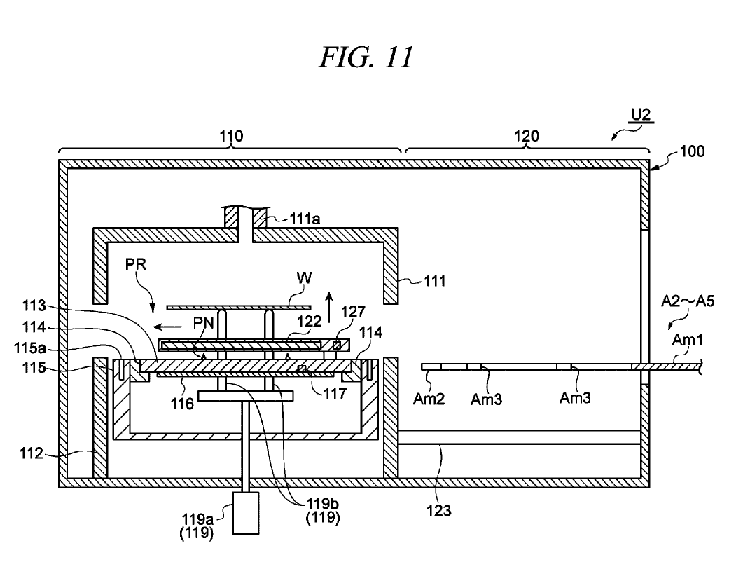

Then, the controller 10 acquires a temperature T of the heat plate 113 at this moment from the temperature sensor 117 and stores the acquired temperature in the storage unit M2 (process S13 of FIG. 8). Thereafter, the controller 10 controls the non-illustrated driving source to move the cover member 111 upwards, as shown in FIG. 11. Then, the controller 10 controls the moving device 124 and the motor 119a to locate the wafer W on the cooling plate 121 on the elevating pins 119b. Thereafter, the controller 10 controls the moving device 124 to retreat the cooling plate 121 from the heating unit 110.

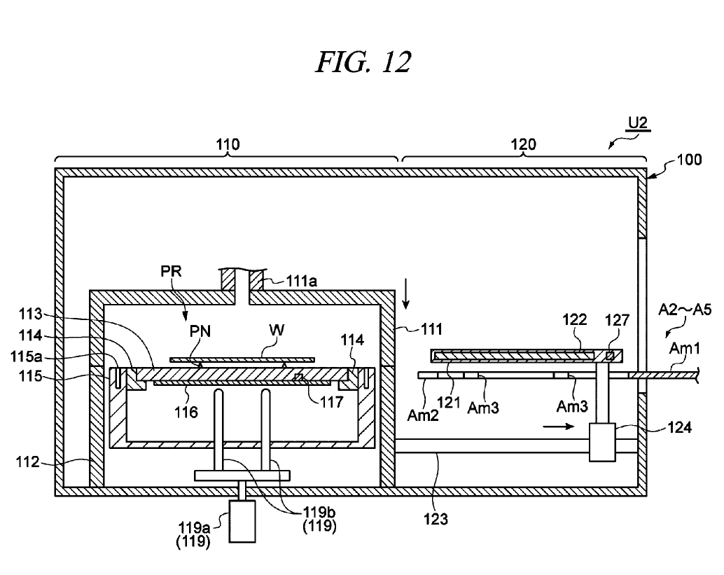

Subsequently, the controller 10 controls the motor 119a to lower the elevating pins 119b, so that the wafer W is supported on the supporting pins PN. Accordingly, the wafer W is placed onto the heat plate 113 from the cooling plate 121 (process S14 of FIG. 8). Then the controller 10 controls the non-illustrated driving source to lower the cover member 111 onto the heat plate accommodation member 112, as shown in FIG. 12. In this state, the wafer W is made to stay on the heat plate 113 for a preset time (e.g., about 20 seconds) (process S15 of FIG. 8). As a result, heat of the heat plate 113 is absorbed by the wafer W, so that the heat plate 113 is cooled and the wafer W is heated.

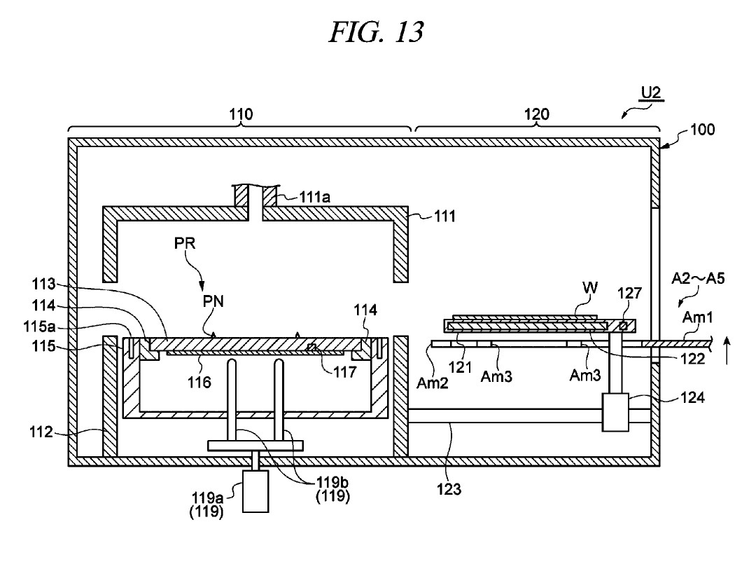

Upon the lapse of the preset time, the controller 10 controls the non-illustrated driving source to move the cover member 111 upwards, as shown in FIG. 11. Then, as shown in FIG. 13, the wafer W is transferred to the cooling plate 121 from the heat plate 113 in the reverse order as the wafer W is transferred to the heat plate 113 from the cooling plate 121 (process S16 of FIG. 8). Accordingly, heat of the wafer W is absorbed by the cooling plate 121, so that the wafer W is cooled.

Subsequently, the controller 10 acquires a temperature of the wafer W indirectly through the cooling plate 121 by receiving the signal from the temperature sensor 127. Then, the controller 10 determines whether the acquired temperature of the wafer W is reduced to the target temperature (process S17 of FIG. 8). Here, the target temperature may be set to be equal to or less than, for example, the heat resistant temperature of the transfer arm A2 (A3 to A5) or be equal to or less than 200° C.

If it is determined that the temperature of the wafer W has not reached the target temperature (NO in the process S17 of FIG. 8), the controller 10 allows the wafer W to be left on the cooling plate 121. Meanwhile, if it is determined that the temperature of the wafer W has reached the target temperature (YES in the process S17 of FIG. 8), the controller 10 stores a cooling time t taken for the wafer W to reach the target temperature in the storage unit M2 in relation to the temperature T of the heat plate 113 (process S18 of FIG. 8).

Then, the controller 10 controls the transfer arm A2 (A3 to A5) to be moved above the cooling plate 121. Accordingly, the wafer W is placed onto the transfer arm A2 (A3 to A5) from the cooling plate 121 (process S19 of FIG. 8). Afterwards, the controller 10 control the transfer arm A1 (A2 to A5) to return the wafer W back into the carrier 11 (process S20 of FIG. 8).

By repeating the aforementioned sequence, there is obtained the correlation data having multiple data in which the temperature T of the heat plate 113 and the cooling time t of the wafer W are matched (first process). An example of these multiple data is shown in Table 1. The correlation data may be a function corresponding to an approximate straight line or an approximate curve of these multiple data or a function corresponding to a polygonal line connecting the neighboring data with straight lines.

TABLE 1

| Temperature T of heat plate 113 | Cooling time t of wafer W | |
|---|---|---|
| 400° C. | 20 | sec |
| 350° C. | 15 | sec |
| 300° C. | 10 | sec |
| 250° C. | 5 | sec |
| 200° C. | 0 | sec |
| 100° C. | 0 | sec |

[Cooling Method for Heat Plate]

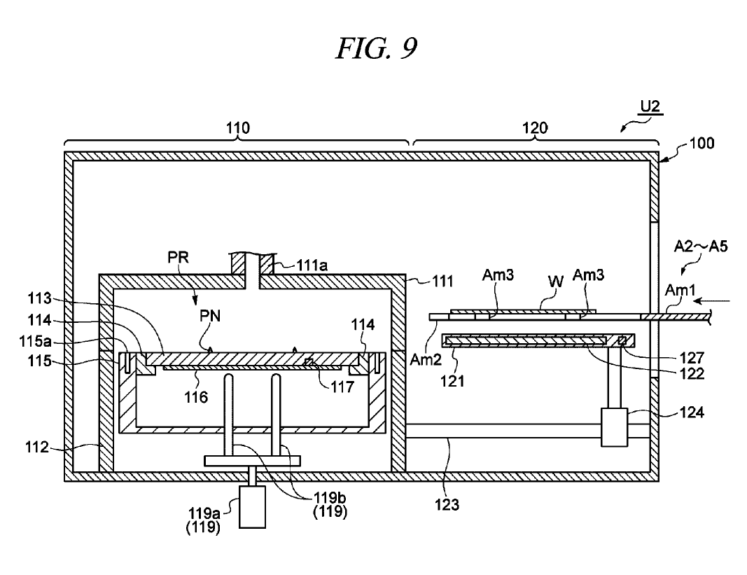

In the unit U2 for heat treatment belonging to each of the modules 14 to 17, the heat treatment of the wafer W is performed while forming the resist pattern on the surface of the wafer W. For this reason, the temperature of the heat plate 113 is relatively high. In the maintenance of the heat plate 113, the heat plate 113 needs to be cooled sufficiently so that an operator can treat the heat plate 113. Now, a method of cooling the heat plate 113 based on the acquired correlation data will be explained with reference to FIG. 9 to FIG. 14. Here, the description will be provided for an example case where the heat plate 113 is cooled from a preset initial temperature to a predetermined cooling completion temperature. The initial temperature may be in the range from, e.g., about 200° C. to about 500° C. The cooling completion temperature may be in the range from, e.g., 30° C. to 300° C.

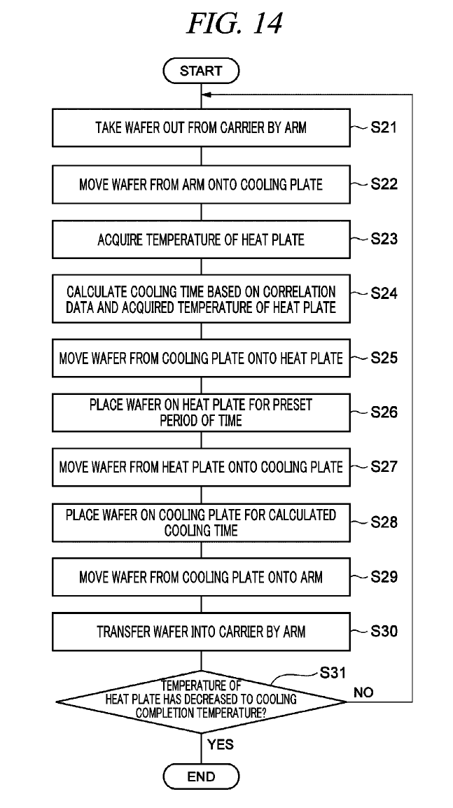

First, as illustrated in FIG. 9, the controller 10 controls the transfer arm A1 (A2 to A5) to take out a single sheet of wafer W from the carrier 11 and transfer the wafer W into the housing 100 of the unit U2 (process S21 of FIG. 14). Subsequently, the controller 10 controls the transfer arm A2 (A3 to A5) to be lowered below the cooling plate 121, as shown in FIG. 10. Accordingly, the wafer W supported by the supporting protrusions Am3 of the transfer arm A2 (A3 to A5) is placed on the cooling plate 121 (process S22 of FIG. 14).

Then, the controller 10 acquires a temperature Tm of the heat plate 113 at this moment from the temperature sensor 117 and stores the acquired temperature in the storage unit M2 (process S23 of FIG. 14; a first processing, a fifth processing, a second process and a sixth process). Next, the controller 10 calculates a cooling time tm required for the wafer W to be cooled to a target temperature based on the temperature Tm of the heat plate 113 acquired by the controller 10 and the correlation data (process S24 of FIG. 14; a third processing, a seventh processing, a fourth process and an eighth process). To be specific, the controller 10 calculates the cooling time tm by inputting the temperature Tm of the heat plate 113 in the correlation data (function), and stores the calculated cooling time tm in the storage unit M2.

Thereafter, the controller 10 controls the non-illustrated driving source to move the cover member 111 upwards, as shown in FIG. 11. Then, the controller 10 controls the moving device 124 and the motor 119a to locate the wafer W on the cooling plate 121 on the elevating pins 119b. Then, the controller 10 controls the moving device 124 to retreat the cooling plate 121 from the heating unit 110.

Subsequently, the controller 10 controls the motor 119a to lower the elevating pins 119b, so that the wafer W is supported on the supporting pins PN. Accordingly, the wafer W is placed onto the heat plate 113 from the cooling plate 121 (process S25 of FIG. 14; a second processing, a sixth processing, a third process, and a seventh process). Then the controller 10 controls the non-illustrated driving source to lower the cover member 111 onto the heat plate accommodation member 112, as shown in FIG. 12. In this state, the wafer W is made to stay on the heat plate 113 for a preset time (e.g., about 20 seconds) (process S26 of FIG. 14). As a result, heat of the heat plate 113 is absorbed by the wafer W, so that the heat plate 113 is cooled and the wafer W is heated.

Upon the lapse of the preset time, the controller 10 controls the non-illustrated driving source to move the cover member 111 upwards, as shown in FIG. 11. Then, as shown in FIG. 13, the wafer W is transferred to the cooling plate 121 from the heat plate 113 in the reverse order as the wafer W is transferred to the heat plate 113 from the cooling plate 121 (process S27 of FIG. 14). In this state, the wafer W is made to stay on the cooling plate 121 for the cooling time tm (process S28 of FIG. 14; a fourth processing, an eighth processing, a fifth process and a ninth process). Accordingly, heat of the wafer W is absorbed by the cooling plate 121, so that the wafer W is cooled.

Thereafter, if the cooling time tm elapses, the controller 10 controls the transfer arm A2 (A3 to A5) to be moved upwards with respect to the cooling plate 121. Accordingly, the wafer W is placed onto the transfer arm A2 (A3 to A5) from the cooling plate 121 (process S29 of FIG. 14; a tenth process). Afterwards, the controller 10 controls the transfer arm A1 (A2 to A5) to return the wafer W back into the carrier 11 (process S30 of FIG. 14).

Then, the controller 10 acquires a temperature of the heat plate 113 from the temperature sensor 117 and determines whether this temperature has reached the cooling completion temperature (process S31 of FIG. 14). If it is determined that the temperature of the wafer W has not reached the cooling completion temperature (NO in the process S31 of FIG. 14), the controller 10 controls the transfer arm A1 (A2 to A5) to take the wafer W from the carrier 11 again and repeats the processes S21 to S31. Meanwhile, if it is determined that the temperature of the wafer W has reached the cooling completion temperature (YES in the process S31 of FIG. 14), the controller 10 ends the cooling processing of the heat plate 113.

[Operations]

In the present exemplary embodiment as stated above, the wafer W heated by the heat plate 113 is cooled by the cooling plate 121 for the cooling time tm which is obtained based on the correlation data and the temperature Tm of the heat plate 113 detected before the wafer W is heated. Therefore, the time period during which the wafer W is cooled by the cooling plate 121 is not of a uniform length but varies depending on the temperature of the heat plate 113. That is, if the heat plate 113 is of a relatively high temperature, the wafer W heated by this heat plate 113 also has a relatively high temperature, so that the cooling time tm of the wafer W by the cooling plate 121 tends to be lengthened. Meanwhile, if the heat plate 113 is of a relatively low temperature, the wafer W heated by this heat plate 113 also has a relatively low temperature, so that the cooling time tm of the wafer W by the cooling plate 121 tends to be shortened. Thus, since the cooling time tm necessary and sufficient for the temperature Tm of the heat plate 113 is set, the time required for the wafer W to reach the target temperature is shortened. Therefore, the heat plate 113 can be cooled in a shorter period of time.

In the present exemplary embodiment, the processes S21 to S31 are repeated until the temperature of the wafer W reaches the cooling completion temperature. Since a temperature Tm1 of the heat plate 113 acquired in the process S23 performed earlier is higher than a temperature Tm2 of the heat plate 113 acquired in the process S23 performed later (Tm1>Tm2), a cooling time tm2 calculated from the temperature Tm2 based on the correlation data is shorter than a cooling time tm1 calculated from the temperature Tm1 based on the correlation data (tm2<tm1). For this reason, while the wafer W is carried into or out of the unit U2 repeatedly, the cooling time tm of the wafer W does not have a uniform length. Therefore, in case of reducing the temperature of the heat plate 113 greatly by carrying the wafer W onto the heat plate 113 and the cooling plate 121 repeatedly, it is possible to cool the heat plate 113 in a short period of time.

In the present exemplary embodiment, the target temperature of the wafer W to be reached through the cooling is set to be equal to or less than the heat resistant temperature of the transfer arms A1 to A5 configured to transfer the wafer W between the carrier 11 and the cooling plate 121. Accordingly, since the wafer W is sufficiently cooled, deformation, the degradation or the damage of the transfer arms A1 to A5 due to the heat from the wafer W is suppressed when the transfer arms A1 to A5 transfer the wafer W. Therefore, it is possible to maintain the function of supporting the wafer W by the transfer arms A1 to A5.

### Modification Examples

So far, the exemplary embodiment has been described in detail. However, various changes and modifications may be made without departing from the scope of the present disclosure.

(1) For the temperature adjustment of the cooling plate 121, other means such as water cooling may be used without being limited to the Peltier element.

(2) In the above-described exemplary embodiment, the transfer of the wafer W between the heat plate 113 and the cooling plate 121 is performed by the cooling plate 121. However, the unit U2 may be equipped with a transfer device configured to transfer the wafer W between the heat plate 113 and the cooling plate 121.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A heat treating apparatus, comprising:
a heat plate configured to supply heat to a substrate;
a cooling plate configured to cool the substrate;
a first transfer device configured to transfer the substrate between the heat plate and the cooling plate;
a temperature sensor configured to acquire a temperature of the heat plate;
a storage unit configured to store therein correlation data showing a relationship between the temperature of the heat plate and a cooling time required for the substrate heated by the heat plate at the corresponding temperature to be cooled to a target temperature by the cooling plate; and
a control unit,
wherein the control unit performs:
a first processing of acquiring the temperature of the heat plate by the temperature sensor;
a second processing of placing, after the first processing, the substrate on the heat plate by controlling the first transfer device;
a third processing of calculating, after the first processing, the cooling time corresponding to the temperature acquired in the first processing based on the correlation data and the temperature acquired in the first processing; and
a fourth processing of placing, after the third processing, the substrate on the cooling plate by controlling the first transfer device and cooling the substrate by the cooling plate for at least the cooling time calculated in the third processing.

2. The heat treating apparatus of claim 1,
wherein the control unit performs:
a fifth processing of acquiring, after the second processing, a temperature of the heat plate by the temperature sensor;
a sixth processing of placing, after the fifth processing, the substrate on the heat plate by using the first transfer device;
a seventh processing of calculating, after the fifth processing, the cooling time corresponding to the temperature acquired in the fifth processing based on the correlation data and the temperature acquired in the fifth processing; and
an eighth processing of placing, after the seventh processing, the substrate on the cooling plate by controlling the first transfer device, and cooling the substrate by the cooling plate for at least the cooling time calculated in the seventh processing.

3. The heat treating apparatus of claim 1, further comprising:
a second transfer device configured to transfer the substrate to/from the cooling plate.

4. The heat treating apparatus of claim 3,
wherein the target temperature is set to be equal to or less than a heat resistant temperature of the second transfer device.

5. A cooling method for a heat plate, comprising:
a first process of acquiring correlation data showing a relationship between a temperature of a heat plate configured to supply heat to a substrate and a cooling time required for the substrate heated by the heat plate at the corresponding temperature to be cooled to a target temperature by a cooling plate configured to cool the substrate;
a second process of acquiring the temperature of the heat plate by a temperature sensor;
a third process of placing, after the second process, the substrate on the heat plate;
a fourth process of calculating, after the second process, the cooling time corresponding to the temperature acquired in the second process based on the correlation data and the temperature acquired in the second process; and
a fifth process of placing, after the fourth process, the substrate on the cooling plate and cooling the substrate by the cooling plate for at least the cooling time calculated in the fourth process.

6. The cooling method of claim 5, further comprising:
a sixth process of acquiring, after the third process, the temperature of the heat plate by the temperature sensor;
a seventh process of placing, after the sixth process, the substrate on the heat plate;
an eighth process of calculating, after the sixth process, the cooling time corresponding to the temperature acquired in the sixth process based on the correlation data and the temperature acquired in the sixth process; and
a ninth process of placing, after the eighth process, the substrate on the cooling plate and cooling the substrate by the cooling plate for at least the cooling time calculated in the eighth process.

7. The cooling method of claim 5, further comprising:
a tenth process of carrying out, after the fifth process, the substrate from the cooling plate by a transfer device.

8. The cooling method of claim 7,
wherein the target temperature is set to be equal to or less than a heat resistant temperature of the transfer device.

9. A computer-readable recording medium having stored thereon computer-executable instructions that, in response to execution, cause a heat treating apparatus to perform a cooling method as claimed in claim 5.
